(19) United States
(12) Patent Application Publication
(10) Pub. No.: US 2008/0157141 A1
(43) Pub. Date: Jul. 3, 2008

(54) CMOS DEVICE AND METHOD OF MANUFACTURING THE SAME

(76) Inventor: Chang Hun Han, Gyeonggi-do (KR)

Correspondence Address: SHERR & NOURSE, PLLC, 620 HERNDON PARKWAY, SUITE 200, HERNDON, VA, 20170, US

(21) Appl. No.: 11/875,419

(22) Filed: Oct. 19, 2007

(30) Foreign Application Priority Data
Dec. 29, 2006 (KR) 10-2006-0137322

(51) Int. Cl. H01L 31/113; H01L 27/146; H01L 31/18

(52) U.S. Cl. 257/292; 438/59; 257/E31.083; 257/E27.133

(57) ABSTRACT

A method of manufacturing a CMOS device including: sequentially forming a first silicon oxide film and a first polysilicon film on a lower substrate; performing an ion implantation process with respect to the first polysilicon film to form a plurality of lower conductors spaced apart from one another at a predetermined interval; forming a plurality of N-type semiconductor films and P-type semiconductor films which are formed by being spaced apart from one another at a predetermined interval and are in contact with the lower conductors; forming a plurality of upper conductors electrically connected to the N-type semiconductor films and P-type semiconductor films; forming an upper substrate on the upper conductors; forming a second polysilicon film on the upper substrate; forming a device isolation film and a photodiode in the second polysilicon film; forming a gate electrode including an insulating sidewall on the second polysilicon film; forming an insulating film on an epitaxial layer with the gate electrode; forming a color filter array on the insulating film; forming a planarization layer on the color filter array; and forming a microlens on the planarization layer.

This application claims the benefit of Korean Patent Application No. P2006-0137322, filed on Dec. 29, 2006, which is hereby incorporated by reference as if fully set forth herein.

### BACKGROUND

An image sensor is a semiconductor device used to convert optical images detected by the image sensor to electric signals. Image sensors may be classified as a charge coupled device (CCD) and a complementary metal oxide semiconductor (CMOS).

A CCD image sensor employs a plurality of metal-oxide-silicon (MOS) capacitors that may be arranged adjacent to each other and charge carriers are stored in and transferred to the capacitors.

A CMOS image sensor is provided with a plurality of MOS transistors corresponding to pixels of a semiconductor device having a control circuit and a signal processing circuit as peripheral circuits. The control circuit and the signal processing unit may be integrated together to employ a switching method that detects output through the MOS transistors.

CCD and CMOS image sensors can be plagued with generating dark current due to increased heat emission during operation.

### SUMMARY

Embodiments relate to a CMOS device and a method of manufacturing the same in which dark prevent is not generated during operation.

Embodiments relate to a CMOS device including a cooling element formed on and/or over a lower substrate; and an image sensor formed on and/or over the cooling element.

In accordance with embodiments, the lower substrate may be formed of a heat sink or a polysilicon film. The cooling element may include a first interlayer insulating film formed on the lower substrate; a plurality of lower conductors which are spaced apart from one another at a predetermined interval in a first silicon insulating film on the first interlayer insulating film; a plurality of N-type semiconductor films and P-type semiconductor films which are alternatively spaced apart from one another at a predetermined interval in a second silicon insulating film on the first silicon insulating film so as to be in contact with the lower conductors; a plurality of upper conductors electrically connected to the N-type semiconductor films and the P-type semiconductor films formed on the second silicon insulating film in series; and an upper substrate formed on the entire surface of the lower substrate with the upper conductors. Each of the lower conductors may include an N-type semiconductor film or an aluminum film.

In accordance with embodiments, the upper conductor may be formed of a P-type semiconductor film or an N-type semiconductor film. The upper substrate may be formed of a silicon oxide film. The image sensor may include a device isolation film and photodiode formed in a polysilicon film on the upper substrate; a gate electrode including an insulating sidewall formed on the polysilicon film; a second insulating film formed on the entire surface of the lower substrate with the gate electrode; a color filter array (CFA) formed on the second insulating film in correspondence with the photodiode; a planarization layer formed on the entire surface of the lower substrate with the CFA; and a microlens formed on the planarization layer in correspondence with the CFA.

Embodiments relate to a method of manufacturing a CMOS device including at least one of the following steps: sequentially forming a first silicon oxide film and a first polysilicon film on and/or over a lower substrate; performing an ion implantation process with respect to the first polysilicon film to form a plurality of lower conductors spaced apart from one another at a predetermined spatial gap; forming a plurality of N-type semiconductor films and P-type semiconductor films, the plurality of N-type semiconductor films and P-type semiconductor films being arranged alternatively spaced apart from one another at a predetermined spatial gap and in contact with the lower conductors; forming a plurality of upper conductors electrically connected to the N-type semiconductor films and P-type semiconductor films; forming an upper substrate on and/or over the upper conductors; forming a second polysilicon film on and/or over the upper substrate; forming a device isolation film and a photodiode in the second polysilicon film; forming a gate electrode including an insulating sidewall on and/or over the second polysilicon film; forming an insulating film on and/or over an epitaxial layer with the gate electrode; forming a color filter array on and/or over the insulating film; forming a planarization layer on and/or over the color filter array; and forming a microlens on and/or over the planarization layer.

In accordance with embodiments, the lower substrate may be formed of a heat sink or a polysilicon film. The lower conductor may include an N-type semiconductor film or an aluminum film. The upper conductor may be formed of a P-type semiconductor film or an N-type semiconductor film.

In accordance with embodiments, a back grinding process may be performed with respect to the back surface of a CMOS device having a silicon on insulator (SOI) such that a silicon oxide film is exposed in the CMOS device, after forming the upper substrate; and coupling the silicon oxide film of the CMOS device to the upper substrate at a predetermined temperature in a range of between approximately 350 to 1350° C. The upper substrate may be formed of a silicon oxide film.

### DRAWINGS

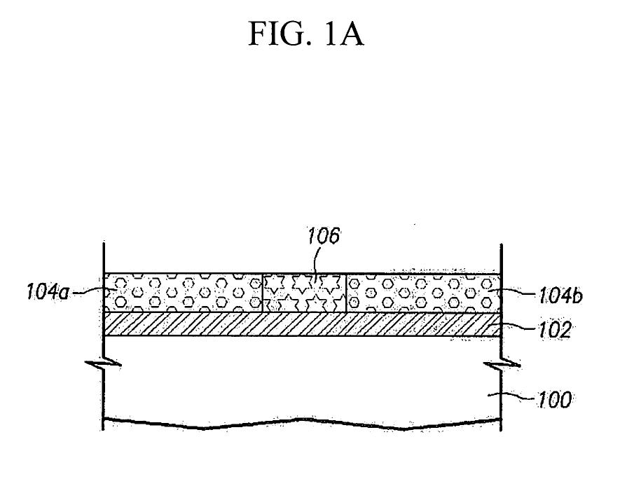

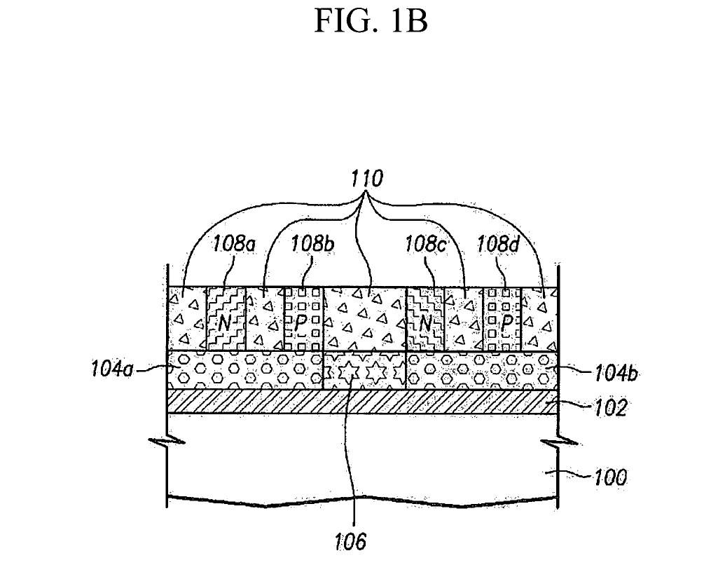

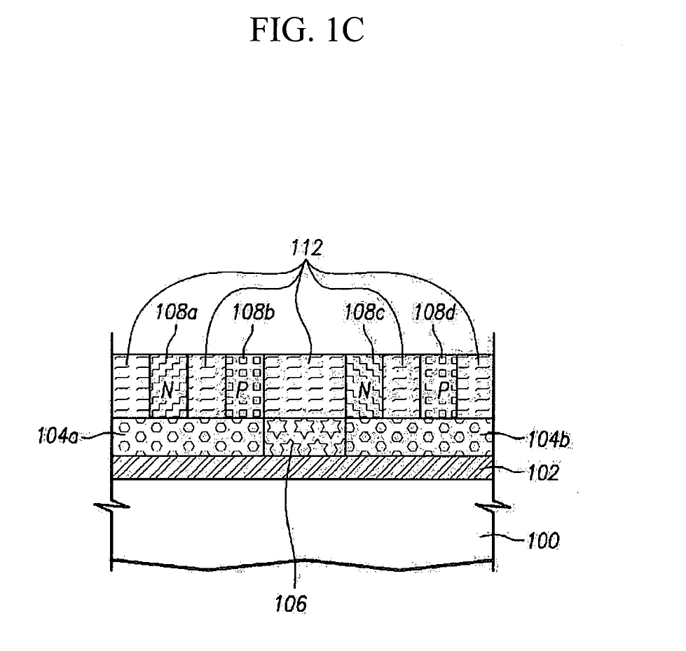

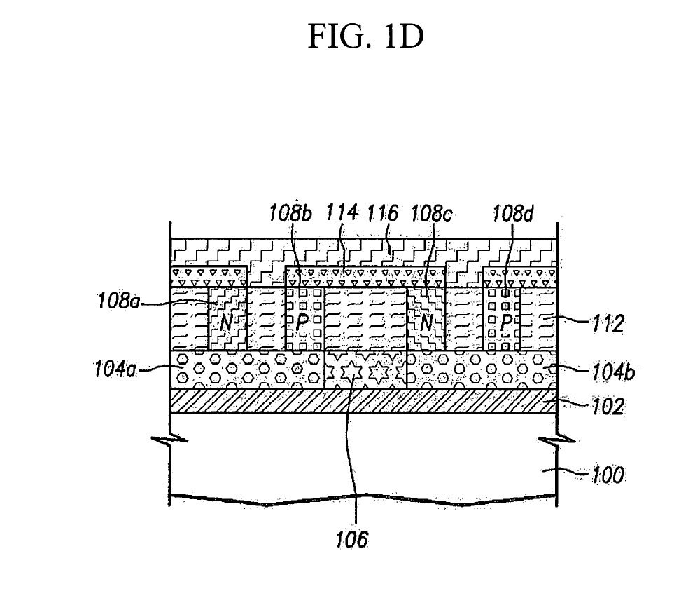

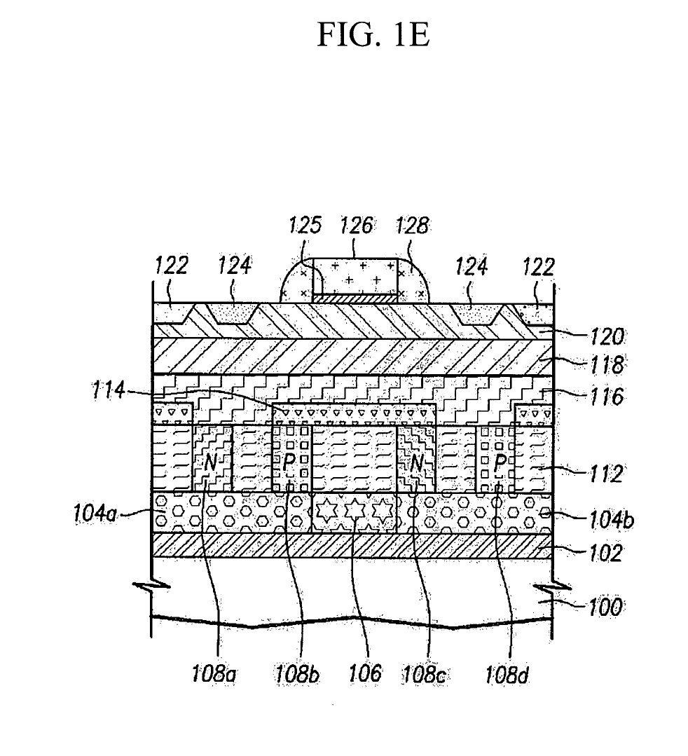

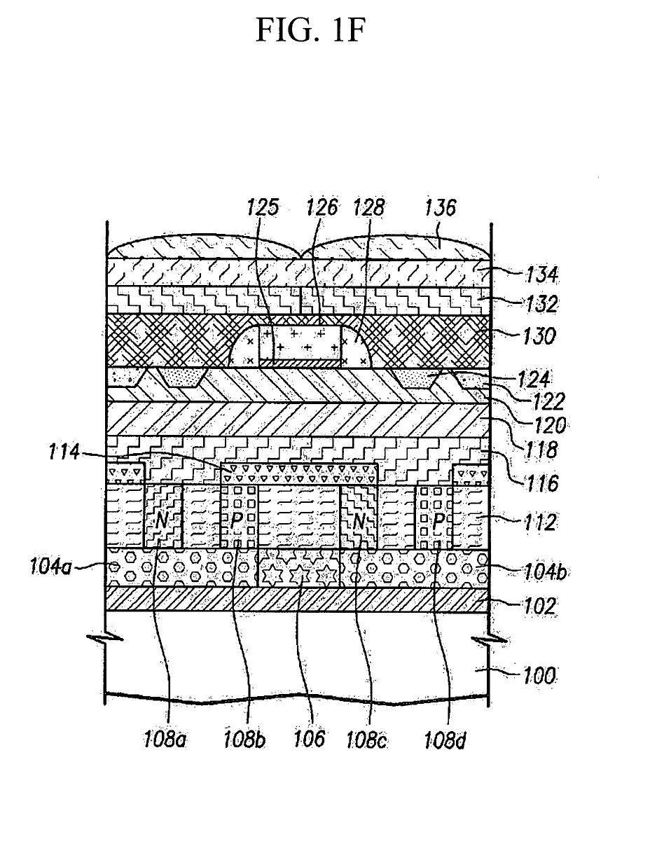

Example FIGS. 1A to 1F illustrate a method of manufacturing a CMOS device, in accordance with embodiments.

### DESCRIPTION

As illustrated in example FIG. 1A, first insulating film 102 and a first polysilicon film can be sequentially deposited having predetermined thicknesses on and/or over lower substrate 100. Lower substrate 100 may be formed of a heat sink or a polysilicon film. First insulating film 102 may be composed of a silicon oxide film (SiO₂) or an aluminum oxide film. First insulating film 102 may have a thickness in a range of between approximately 10 to 300 μm.

Thereafter, a first photoresist pattern can be formed on and/or over the first polysilicon film. An ion implantation process using the first photoresist pattern as a mask can then be performed such that dopant ions are implanted into the first polysilicon film to form first lower conductor 104a, second lower conductor 104b and first region 106 provided between first lower conductor 104a and second lower conductor 104b. First lower conductor 104a and second lower conductor 104b can be spaced apart from each other at a predetermined spatial gap, the gap into which first region 106 is provided. Ashing and cleaning processes can then be performed to remove the first photoresist pattern.

First lower conductor 104a and second lower conductor 104b may be formed of a metal film such as an aluminum film or an N-type semiconductor film into which n-type dopant ions are implanted. Dopant ions are not implanted into first region 106.

As illustrated in example FIG. 1B, a second polysilicon film can be deposited on and/or over first polysilicon film including first lower conductor 104a, second lower conductor 104b and first region 106. A second photoresist pattern can be formed on and/or over the second polysilicon film.

Thereafter, an ion implantation process using the second photoresist pattern as a mask can be performed such that n-type dopant ions and p-type dopant ions are alternately implanted into the second polysilicon film to form N-type semiconductor films 108a, 108c and P-type semiconductor films 108b, 108d. N-type semiconductor films 108a, 108c and P-type semiconductor films 108b, 108d can respectively be in contact with first lower conductor 104a and second lower conductor 104b and may also be spaced apart from each other at a predetermined spatial gap or interval. Ashing and cleaning processes may then be performed to remove the second photoresist pattern. At this time, the second polysilicon film includes second region 110 into which dopant ions are implanted.

As illustrated in example FIG. 1C, a third photoresist pattern can be formed on and/or over the second polysilicon film. An etching process using the third photoresist pattern using a mask can be performed such that the second polysilicon film of the second region 110 is selectively etched to form a second polysilicon film pattern including a trench. Ashing and cleaning processes can then be performed to remove the third photoresist pattern.

Thereafter, a second insulating film can be deposited on and/or over the second polysilicon film pattern to bury the trench. The second insulating film can be subjected to a planarization process such that N-type semiconductor films 108a, 108c and P-type semiconductor films 108b, 108d are exposed, thereby forming second insulating film pattern 112.

As illustrated in example FIG. 1D, a third polysilicon film can be deposited on and/or over second insulating film pattern 112. A fourth photoresist pattern can then be formed on and/or over the third polysilicon film, and an ion implantation process using the fourth photoresist pattern as a mask can be performed to form upper conductor 114 for connecting N-type semiconductor films 108a, 108c and P-type semiconductor films 108b, 108d in series in the third polysilicon film. Upper conductor 114 may be formed of an N-type semiconductor film or a P-type semiconductor film.

A fifth photoresist pattern can then be formed on and/or over the third polysilicon film. An etching process using the fifth photoresist pattern as a mask can then be performed such that the third polysilicon film, into which the dopant ions are not implanted and which is located at the both sides of upper conductor 114, is selectively etched. Ashing and cleaning processes can then be performed to remove the fifth photoresist pattern.

Thereafter, upper substrate 116 can be formed on and/or over the entire surface of lower substrate 100 including upper conductor 114, thereby completing a Peltier element. Upper substrate 116 may be formed of a silicon oxide film.

When power is supplied to first lower conductor 104a and second lower conductor 104b of the Peltier element, current flows into N-type semiconductor film 108c via second lower conductor 104b. Current flows into first lower conductor 104a via upper conductor 114 and P-type semiconductor film 108b. During this time, heat radiation occurs in upper conductor 114 and heat absorption occurs in lower substrate 100, thereby performing cooling of the semiconductor device. In accordance with embodiments, it is possible to decrease the temperature of the CMOS device manufactured as a Peltier element.

As illustrated in example FIG. 1E, fourth polysilicon film 118 and epitaxial layer 120 can be sequentially formed on and/or over upper substrate 116 of the Peltier element. Device isolation film 122 can then be formed in a device isolation region of epitaxial layer 120. Device isolation film 122 may be formed using a shallow trench isolation (STI) process or a local oxidation of silicon (LOCOS) process.

Thereafter, gate insulating film 125 and a material layer for a gate electrode can be deposited on and/or over epitaxial layer 120. The material layer and gate insulating film 125 can be selectively etched using a photoresist process and an etching process to form gate electrode 126 in an active region defined by device isolation film 122.

Thereafter, a third insulating film can be deposited on and/or over the entire surface of epitaxial layer 120 with gate electrode 126. An etch-back process can then be performed on the entire surface of the third insulating film to form insulating sidewalls 128 laterally at the both sides of gate electrode 126. Photodiode 124 can be provided to generate charges in accordance with the amount of incident light. Photodiode 124 can be formed by implanting dopant ions into epitaxial layer 120.

As illustrated in example FIG. 1F, interlayer insulating film 130 can be formed on and/or over device isolation film 122, photodiode 124, gate insulating film 125, gate electrode 126 and insulating sidewalls 128. Interlayer insulating film 130 can be coated with resist layers of blue, red and green. Exposure and development processes can be performed to form color filter array (CFA) 132 for filtering light in accordance with wavelengths.

Hereinafter, planarization layer 134 can be formed on and/or over CFA 132. A material layer for forming a microlens can then be coated on and/or over planarization layer 134. Exposure and development processes can be performed to pattern the material layer to form microlens 136, thereby completing a Peltier CMOS device.

To create a CMOS device having a silicon-on-insulator (SOI) structure, the back surface of the CMOS device can be subjected to a back grinding process to expose a silicon oxide film. The silicon oxide film can then be coupled to the silicon oxide film of the Peltier element formed previously at a predetermined temperature such as approximatgelt 350 to 1350° C., thereby completing the CMOS device.

In accordance with embodiments, a Peltier CMOS device and a method of manufacturing the same can be advantageous for reducing the operating temperature and thereby prevent dark current from being generated.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a cooling element formed on a lower substrate; and
an image sensor formed on the cooling element.

2. The apparatus of claim 1, wherein the lower substrate is formed of a heat sink or a polysilicon film.

3. The apparatus of claim 1, wherein the lower substrate is formed of a polysilicon film.

4. The CMOS device according to claim 1, wherein the cooling element comprises:
a first interlayer insulating film formed over the lower substrate;
a plurality of lower conductors in a first silicon insulating film on the first interlayer insulating film;
a plurality of N-type semiconductor films and P-type semiconductor films in a second silicon insulating film on the first silicon insulating film so as to be in contact with the plurality of lower conductors;
a plurality of upper conductors formed over the second silicon insulating film in series and electrically connected to the N-type semiconductor films and the P-type semiconductor films; and
an upper substrate formed over the entire surface of the lower substrate.

5. The apparatus of claim 4, wherein the plurality of lower conductors are arranged in a spaced apart pattern at a predetermined interval and the plurality of N-type semiconductor films and P-type semiconductor films are arranged in a spaced apart pattern at a predetermined interval.

6. The apparatus of claim 5, wherein the lower conductor includes an N-type semiconductor film or an aluminum film.

7. The apparatus of claim 5, wherein the lower conductor includes an aluminum film.

8. The apparatus of claim 5, wherein the upper conductor is formed of a P-type semiconductor film or an N-type semiconductor film.

9. The apparatus of claim 5, wherein the upper conductor is formed of an N-type semiconductor film.

10. The apparatus of claim 5, wherein the upper substrate is formed of a silicon oxide film.

11. The apparatus of claim 5, wherein the image sensor comprises:
a device isolation film formed in a polysilicon film on the upper substrate;
a photodiode formed in a polysilicon film on the upper substrate;
a gate electrode including an insulating sidewall formed over the polysilicon film;
a second insulating film formed over the entire surface of the lower substrate including the gate electrode;
a color filter array formed over the second insulating film in correspondence with the photodiode;
a planarization layer formed over the entire surface of the lower substrate including the color filter array; and
a microlens formed over the planarization layer in correspondence with the color filter array.

12. A method comprising:
sequentially forming a first silicon oxide film and a first polysilicon film over a lower substrate;
performing an ion implantation process on the first polysilicon film to form a plurality of lower conductors spaced apart from one another at a predetermined interval;
forming a plurality of N-type semiconductor films and P-type semiconductor films in a spaced apart arrangement from each other at a predetermined interval, wherein the plurality of N-type semiconductor films and P-type semiconductor films are in contact with the plurality of lower conductors;
forming a plurality of upper conductors electrically connected to the N-type semiconductor films and P-type semiconductor films;
forming an upper substrate over the upper conductors;
forming a second polysilicon film over the upper substrate;
forming a device isolation film and a photodiode in the second polysilicon film;
forming a gate electrode including an insulating sidewall over the second polysilicon film;
forming an insulating film over an epitaxial layer with the gate electrode;
forming a color filter array over the insulating film;
forming a planarization layer over the color filter array; and then forming a microlens over the planarization layer.

13. The method of claim 12, wherein the lower substrate is formed of a heat sink or a polysilicon film.

14. The method of claim 12, wherein the lower substrate is formed of a polysilicon film.

15. The method of claim 12, wherein the lower conductor includes an N-type semiconductor film or an aluminum film.

16. The method of claim 12, wherein the lower conductor includes an aluminum film.

17. The method of claim 12, wherein the upper conductor is formed of a P-type semiconductor film or an N-type semiconductor film.

18. The method of claim 12, wherein the upper conductor is formed of an N-type semiconductor film.

19. The method of claim 12, further comprising:
performing a back grinding process with respect to the back surface of a CMOS device after forming the upper substrate, wherein the CMOS has a silicon on insulator structure such that a silicon oxide film is exposed in the CMOS device; and
coupling the silicon oxide film of the CMOS device to the upper substrate at a predetermined temperature of between approximately 350 to 1350° C.

20. The method of claim 12, wherein the upper substrate is formed of a silicon oxide film.
